(19) United States
(12) Patent Application Publication
(10) Pub. No.: US 2009/0152735 A1
(43) Pub. Date: Jun. 18, 2009

(54) Metal Interconnection and Method for Manufacturing the Same in a Semiconductor Device

(76) Inventors: Han Choon Lee, Songpa-gu (KR); In Cheol Baek, Suwon-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/241,212

(22) Filed: Sep. 30, 2008

(30) Foreign Application Priority Data
Dec. 17, 2007 (KR) 10-2007-0132398

(51) Int. Cl. H01L 23/48; H01L 21/4763

(52) U.S. Cl. 257/774; 438/637; 257/E23.01; 257/E21.495

(57) ABSTRACT

Provided is a method for manufacturing a metal interconnection in a semiconductor device. The semiconductor device fabricated according to one embodiment comprises a copper interconnection having reduced sheet and contact resistance. In the method for manufacturing the copper interconnection, a dielectric comprising a via hole is formed on a semiconductor substrate. A diffusion barrier is deposited in the via hole of the dielectric using a process including a plasma enhanced atomic layer deposition (PEALD) process. A copper metal layer can be formed on the via hole through an electroplating process.

### CROSS-REFERENCE TO RELATED APPLICATION

The present application claims the benefit under 35 U.S.C. §119 of Korean Patent Application No. 10-2007-0132398, filed Dec. 17, 2007, which is hereby incorporated by reference in its entirety.

### BACKGROUND

In general, in an interconnection formation process of a semiconductor device or an electronic device, a conductive material such as aluminum (Al) or tungsten (W) is deposited on a dielectric to form a conductive layer. The conductive layer is then patterned using a photolithography process and a dry etching process to form an interconnection. The above-described interconnection formation process is widely used in the field of semiconductor or electronic device manufacturing. Recently, as a semiconductor device, such as a logic device, requires a high operating speed, interconnection forming technology that can use a material having a low specific resistance, such as copper (Cu), instead of aluminum or tungsten as the interconnection material is being developed in order to reduce resistance capacitance (RC) delay time.

However, in the interconnection formation process using copper, a diffusion barrier is disposed between a dielectric and a copper interconnection in order to prevent copper particles from being diffused into the dielectric.

The diffusion barrier generally has a bi-layer structure including tantalum nitride/tantalum (TaN/Ta) and is deposited using a physical vapor deposition (PVD) process.

When a device size is about 65 nm node or less, the diffusion barrier must be about 5 nm or less in thickness. As a result, it is difficult to obtain conformal step coverage using the PVD process, resulting in copper voids due to overhang.

### BRIEF SUMMARY

Embodiments of the present invention provide a method for manufacturing a metal interconnection in a semiconductor device.

In one embodiment, a method for manufacturing a metal interconnection in a semiconductor device comprises: forming a dielectric comprising a via hole on a semiconductor substrate; attaching a precursor material on the dielectric and flowing argon and hydrogen on the dielectric having the attached precursor material to form a TaN layer on the dielectric using a plasma enhanced atomic layer deposition process; forming a Ta layer on the TaN layer using a physical vapor deposition process; and forming a metal layer in the via hole comprising the TaN layer and the Ta layer.

In another embodiment, a metal interconnection in a semiconductor device is provided that comprises: a substrate comprising a lower interconnection; an interlayer dielectric on the substrate, the interlayer dielectric comprising a via hole exposing a portion of the lower interconnection; a TaN layer in which an atomic layer is repeatedly stacked in the via hole, where the TaN layer has a reduced sheet resistance; a Ta layer on the TaN layer in the via hole; and a copper interconnection filled in the via hole.

Embodiments of the present invention utilize a plasma enhanced atomic layer deposition (PEALD) process to deposit a diffusion barrier in a semiconductor device to reduce a resistance and ensure uniformity of a layer thickness.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view illustrating a copper interconnection of a semiconductor device according to an embodiment of the present invention.

FIG. 2 is a flowchart illustrating a process for manufacturing a copper interconnection of a semiconductor device according to an embodiment of the present invention.

FIG. 3 is a graph illustrating results obtained using an auger electron spectroscopy (AES) analyzer after a copper layer is annealed in a semiconductor device fabricated according to an embodiment of the present invention.

FIG. 4A is a graph illustrating an X-ray photon spectroscopy (XPS) analysis result about a characteristic of TaN deposited using a PVD process in a semiconductor device.

FIG. 4B is a graph illustrating an XPS analysis result about a characteristic of TaN deposited using a PEALD process in a semiconductor device according to an embodiment of the present invention.

FIG. 5 is a table illustrating sheet resistances of a diffusion barrier of a copper interconnection before and after a post-process in a semiconductor device according to embodiments of the present invention.

### DETAILED DESCRIPTION

Hereinafter, a metal interconnection of a semiconductor device and a method for manufacturing the same according to an embodiment will be described in detail with reference to the accompanying drawings. In addition, it will also be understood that when terms such as “first” and “second” are used to describe certain elements, the elements are not limited by these terms. For example, a plurality of elements may be provided. Therefore, when the terms such as “first” and “second” are used, it will be apparent that the plurality of elements may be provided. In addition, the terms “first” and “second” can be selectively or exchangeably used for the elements.

In the figures, a dimension of each of elements may be exaggerated for clarity of illustration, and the dimension of each of the elements may be different from an actual dimension of each of the elements. Not all elements illustrated in the drawings must be included or are limited to the present disclosure, but the elements except essential features of the present disclosure may be added or deleted. Also, in the descriptions of embodiments, it will be understood that when a layer (or film) is referred to as being ‘on/above/over/upper’ another layer or substrate, it can be directly on the another layer or substrate, or intervening layers may also be present. Further, it will be understood that when a layer is referred to as being ‘under/below/under/lower’ another layer, it can be directly under the another layer, or one or more intervening layers may also be present. Therefore, meaning thereof should be judged according to the spirit of the present disclosure.

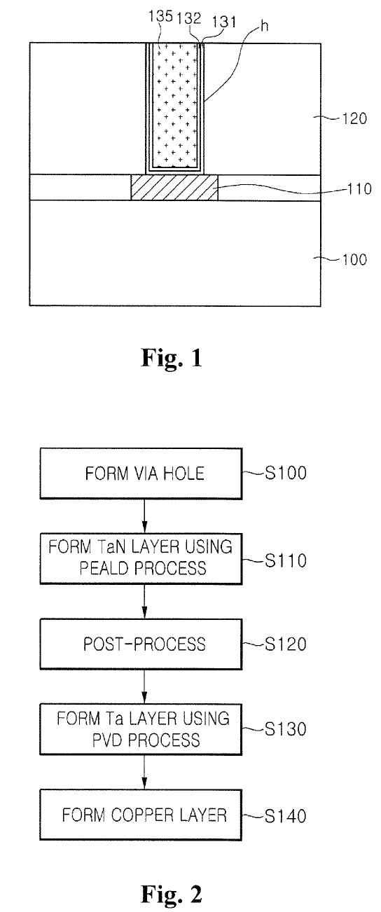

FIG. 1 is a cross-sectional view illustrating a copper interconnection of a semiconductor device according to an embodiment, and FIG. 2 is a flowchart illustrating a process for manufacturing a copper interconnection of a semiconductor device according to an embodiment.

Referring to FIGS. 1 and 2, an interlayer dielectric 120 can be formed on a lower structure (not shown) of a semiconductor substrate 100 including a lower interconnection 110. In operation S100, a contact hole or a via hole h can be formed in the interlayer dielectric 120.

A portion of the lower interconnection 110 is exposed by the via hole h formed in the interlayer dielectric 120.

In certain embodiments, a trench connected to the via hole h can also be formed in the interlayer dielectric 120.

A diffusion barrier having a bi-layer structure can be formed in the via hole h. The bi-layer structure can include a first barrier metal layer 131 formed in the via hole h using plasma enhanced atomic layer deposition (PEALD) and a second barrier metal layer 132 formed on the first barrier metal layer 131 using a physical vapor deposition process (PVD). In a specific embodiment, the bi-layer structure can be a tantalum (Ta) layer 132 and a tantalum nitride (TaN) layer 131 structure (a Ta/TaN structure).

In operation S110, the TaN layer 131 can be formed using PEALD process. In certain embodiments, the TaN layer 131 can be formed to a thickness ranging from about 30 Å to about 200 Å.

According to an embodiment, a reaction material is attached to the substrate 100. The reaction material can be a precursor material of the TaN layer 131. In one embodiment, tert-amylimidotrisdim-ethylamidotantalum (TAIMATA) is used as the precursor of the TaN layer 131. In an embodiment, the reaction time can be in a range of about 1 second to about 10 seconds.

Reaction material that is not attached to the substrate 100 can be discharged outside a chamber used for the deposition process.

Within the chamber used for the deposition process, argon (Ar) plasma having a flow rate ranging from about 100 sccm to about 500 sccm and H₂ plasma having a flow rate ranging from about 200 sccm to about 1000 sccm flow onto the substrate 100 to form the TaN layer 131. In an embodiment, the reaction time can be in a range of about 1 second to about 30 seconds.

Thereafter, remaining gases and reaction products are discharged to the outside of the chamber.

One atomic layer of TaN may be formed after performing the above-described process once. Accordingly, the process may be repeatedly performed to form the TaN layer 131 having a required or desired thickness.

When the diffusion barrier is formed using the above-described method, a layer quality having a low sheet resistance and a uniform thickness can be obtained.

In the post process operation S120, after the TaN layer 131 is formed to the appropriate thickness (which may take multiple repetitions of the PEALD process described above), the TaN layer 131 can be annealed for a time ranging from about 30 seconds to about 100 seconds and at a temperature ranging from about 200° C. to about 300° C. while H₂ having a flow rate ranging from about 500 sccm to about 1200 sccm. In another embodiment of the post process operation S120, the TaN layer 131 can be annealed for a time ranging from about 30 seconds to about 100 seconds at a temperature ranging from about 200° C. to about 300° C. while NH₃ having a flow rate ranging from about 800 sccm to about 2000 sccm flows.

In operation S130, the Ta layer 132 can be formed using a physical vapor deposition process, such as sputtering. In certain embodiments, the Ta layer 132 can be formed to a thickness of about 400 Å or less.

In operation S140, a copper layer can be formed in the via hole h. In one embodiment, a seed layer such as a copper seed layer (not shown) can be formed in the via hole h. Then, a copper layer can be formed using an electro chemical plating (ECP) process.

When copper is filled in the via hole h, an annealing process may be performed in order to crystallize copper formed using an electroplating.

The metal layer can be planarized using a chemical mechanical polishing (CMP) process to form a metal interconnection 135.

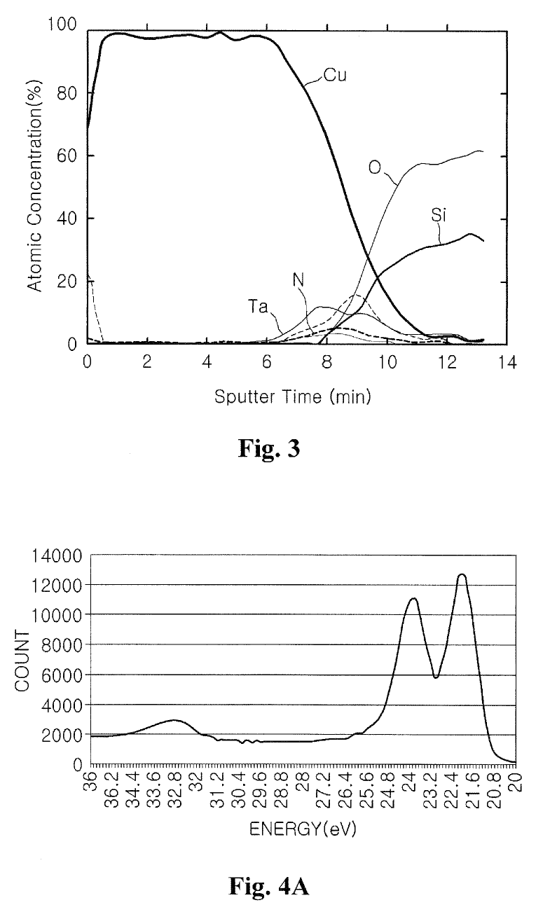

FIG. 3 is a graph illustrating results obtained using an auger electron spectroscopy (AES) analyzer after the copper layer of a semiconductor device according to an embodiment is annealed.

As can be seen from FIG. 3, in compositions of a copper layer, a diffusion barrier, and an interlayer dielectric according to a sputtering time, copper detected from a copper layer is significantly shown during an initial time period, Ta and N detected from a diffusion barrier are significantly shown during an intermediate time period, and oxygen (O) and silicon (Si) detected from an interlayer dielectric are significantly shown during a last time period.

The composition of the copper layer is not detected again while the compositions of the interlayer dielectric are detected. As a result, this denotes that copper particles are not diffused from the copper layer to the interlayer dielectric after the annealing process.

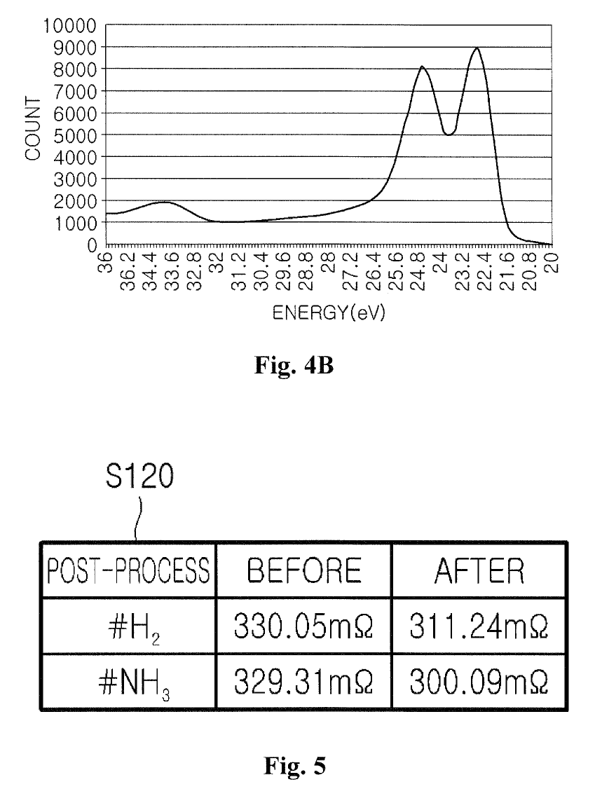

FIG. 4A is a graph illustrating an X-ray photon spectroscopy (XPS) analysis result about a characteristic of TaN deposited using a PVD process in a semiconductor device, and FIG. 4B is a graph illustrating an XPS analysis result about a characteristic of TaN deposited using a PEALD process in a semiconductor device as performed according to an embodiment of the present invention.

When an X-ray is irradiated onto a TaN layer, the TaN layer absorbs the X-ray to emit electrons. The emitted electrons are detected using a detector, and the detected results are analyzed to determine characteristics of the TaN layer.

As can be seen from FIGS. 4A and 4B, according an XPS analysis result, the TaN layer deposited using the PVD process has the substantially same characteristics as the TaN layer deposited using the PEALD process.

FIG. 5 is a table illustrating sheet resistances of a diffusion barrier of a Cu interconnection before and after a post-process (operation S120) in a semiconductor device according to an embodiment.

Referring to FIG. 5, after a TaN layer is formed using a method according to an embodiment, for operation S120, the TaN layer can be annealed for about 60 seconds at about 250° C. while H₂ having a flow rate ranging from about 500 sccm to about 1200 sccm flows onto the substrate. The sheet resistance is measured before and after the operation S120. According to the measured result, the sheet resistance of the TaN layer decreases from 330.05 mΩ to 311.24 mΩ.

In addition, after a TaN layer is formed using a method according to an embodiment, for operation S120, the TaN layer can be annealed for about 60 seconds at about 250° C. while NH₃ having a flow rate ranging from about 800 sccm to about 2000 sccm flows onto the substrate. The sheet resistance is measured before and after the operation S120. According to the measured result, the sheet resistance of the TaN layer decreases from 329.31 mΩ to 300.09 mΩ.

The TaN layer, i.e., a diffusion barrier formed using the PEALD process can have a low contact resistance value applicable to mass production compared to the TaN layer formed using the using the PVD process. When a post-process is performed on the TaN layer formed using the PEALD process, the diffusion barrier having a much lower contact resistance can be formed.

In the semiconductor device according to the embodiments, the diffusion barrier can be deposited using the PEALD process to reduce the resistance and ensure uniformity of the layer thickness. As a result, copper voids due to overhang can be inhibited from occurring to improve the yield.

In the semiconductor device according to the embodiments, a specific resistance of the diffusion barrier can be reduced to reduce the sheet resistance and the contact resistance, thereby improving device characteristics.

Any reference in this specification to “one embodiment,” “an embodiment,” “exemplary embodiment,” etc., means that a particular feature, structure, or characteristic described in connection with the embodiment is included in at least one embodiment of the disclosure. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with others of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. For example, elements described in detail in the embodiment of the present disclosure can be modified, and differences associated with these variations and modifications should be construed to be included in the scope of the present disclosure defined by the appended claims. In addition to variations and modifications in the component parts and/or arrangements, alternative uses will also be apparent to those skilled in the art.

What is claimed is:

1. A method for manufacturing a metal interconnection in a semiconductor device, the method comprising:
forming a dielectric comprising a via hole on a semiconductor substrate;
forming a first barrier metal layer on the dielectric using a plasma enhanced atomic layer deposition (PEALD) process;
forming a second barrier metal layer on the first barrier metal layer using a physical vapor deposition process (PVD); and
forming a metal layer in the via hole comprising the first barrier metal layer and the second barrier metal layer.

2. The method according to claim 1, wherein forming the first barrier metal layer comprises forming a TaN layer on the dielectric using the PEALD process, and
wherein forming the second barrier metal layer comprises forming a Ta layer on the TaN layer using PVD.

3. The method according to claim 2, wherein forming the TaN layer using the PEALD process comprises:
attaching a precursor material on the dielectric; and
flowing argon and hydrogen on the dielectric having the attached precursor material.

4. The method according to claim 3, wherein the precursor material is tert-amylimidotrisdim-ethylamidotantalum (TAIMATA).

5. The method according to claim 3, wherein flowing the argon comprises using a flow rate ranging from about 100 sccm to about 500 sccm, and flowing the hydrogen comprises using a flow rate ranging from about 200 sccm to about 1000 sccm.

6. The method according to claim 3, further comprising annealing the TaN layer at a temperature ranging from about 200° C. to 300° C. while H₂ having a flow rate ranging from about 500 sccm to about 1200 sccm flows onto the substrate.

7. The method according to claim 3, further comprising annealing the TaN layer at a temperature ranging from about 200° C. to 300° C. while NH₃ having a flow rate ranging from about 800 sccm to about 2000 sccm flows onto the substrate.

8. The method according to claim 1, wherein forming the metal layer comprises:
forming a copper seed layer on the via hole; and
performing an electroplating process to form a copper layer on the copper seed layer.

9. The method according to claim 8, further comprising performing annealing process to crystallize the copper layer.

10. The method according to claim 1, further comprising performing a chemical mechanical polishing process to form a metal line comprising the metal layer, second barrier metal layer, and first barrier metal layer in the via hole.

11. A metal interconnection in a semiconductor device, comprising:
a substrate comprising a lower interconnection;
an interlayer dielectric on the substrate, the interlayer dielectric comprising a via hole exposing a portion of the lower interconnection;
a first barrier metal layer of which an atomic layer is repeatedly stacked in the via hole;
a second barrier metal layer on the first barrier layer in the via hole; and
a metal layer filled in the via hole.

12. The metal interconnection according to claim 11, wherein the first barrier metal layer is a TaN layer, and wherein the second barrier metal layer is a Ta layer.

13. The metal interconnection according to claim 12, wherein the TaN layer has a reduced sheet resistance.

14. The metal interconnection according to claim 12, wherein the reduced sheet resistance is a reduced sheet resistance of the TaN layer reduced by a post-processing annealing at a temperature ranging from about 200° C. to 300° C. while H₂ having a flow rate ranging from about 500 sccm to about 1200 sccm flows over the TaN layer.

15. The metal interconnection according to claim 12, wherein the reduced sheet resistance is a reduced sheet resistance of the TaN layer reduced by a post-processing annealing at a temperature ranging from about 200° C. to 300° C. while NH₃ having a flow rate ranging from about 800 sccm to about 2000 sccm flows over the TaN layer.

16. The metal interconnection according to claim 12, wherein the atomic layer of the TaN layer is formed using a plasma enhanced atomic layer deposition process.

17. The metal interconnection according to claim 12, wherein the TaN layer has a thickness ranging from about 30 Å to about 200 Å.

18. The metal interconnection according to claim 11, wherein the second barrier metal layer is formed using a sputtering process.

19. The metal interconnection according to claim 11, further comprising a seed layer between the second barrier metal layer and the metal layer.

20. The metal interconnection according to claim 11, wherein the metal layer comprises copper.
